(19) United States
(12) Patent Application Publication
(10) Pub. No.: US 2021/0234029 A1
(43) Pub. Date: Jul. 29, 2021

(54) SEMICONDUCTOR DEVICE

(71) Applicant: FUJITSU LIMITED, Kawasaki-shi (JP)

(72) Inventor: Atsushi YAMADA, Hiratsuka (JP)

(73) Assignee: FUJITSU LIMITED, Kawasaki-shi (JP)

(21) Appl. No.: 17/128,785

(22) Filed: Dec. 21, 2020

(30) Foreign Application Priority Data
Jan. 28, 2020 (JP) 2020-011462

(51) Int. Cl. H01L 29/778; H01L 21/02; H01L 29/43; H01L 29/66; H01L 29/20; H01L 29/423; H01L 29/51

(52) U.S. Cl. CPC H01L 29/7786; H01L 21/02505; H01L 21/0254; H01L 29/518; H01L 29/66462; H01L 29/2003; H01L 29/42316; H01L 29/432

(57) ABSTRACT

A disclosed semiconductor device includes an electron transit layer; an electron supply layer disposed on or above the electron transit layer; and a capping layer disposed on or above the electron supply layer, wherein a first lattice constant of the electron transit layer is greater than a second lattice constant of the electron supply layer in a direction parallel to a main surface of the electron transit layer.

### CROSS-REFERENCE TO RELATED APPLICATIONS

The present application is based upon and claims the benefit of priority from the prior Japanese Patent Application No. 2020-011462 filed on Jan. 28, 2020, with the Japanese Patent Office, the entire contents of which are incorporated herein by reference.

### FIELD

The disclosure relates to a semiconductor device.

### BACKGROUND

As a semiconductor device using a nitride semiconductor, a large number of reports have been made on field effect transistors, particularly high electron mobility transistors (HEMT) As such high HEMTs having a nitride semiconductor, HEMTs having a GaN layer as a channel layer and an AlGaN layer as a barrier layer are known. In such GaN-based HEMTs, the AlGaN layer is strained due to the difference between the lattice constant for AlGaN and GaN. This strain is followed by piezoelectric polarization, and a high concentration of a two-dimensional electron gas (2DEG) is then generated near a top face of the GaN layer beneath the AlGaN layer. This results in a high power output.

In HEMT, the concentration of 2DEG may preferably be changed between the source and drain electrodes. For example, the concentration of 2DEG may be preferably higher between the gate and source electrodes than between the gate and drain electrodes in order to maintain both reduction in on-resistance and enhancement in drain breakdown voltage. It is often preferable that there be very little 2DEG present beneath the gate electrode in order to achieve a normally-off operation/

Related art technologies propose a semiconductor device having a stress film on a barrier layer, or a semiconductor device having a p-type GaN layer or an InGaN layer beneath a gate electrode in order to modulate the concentration of 2DEG.

### RELATED-ART DOCUMENTS

### Patent Documents

[Patent Document 1] Japanese Laid-Open Patent Publication No. 2005-183551
[Patent Document 2] Japanese Laid-Open Patent Publication No. 2019-96739
[Patent Document 3] Japanese Laid-Open Patent Publication No. 2009-267155
[Patent Document 4] Japanese Laid-Open Patent Publication No. 2009-76845

### Non-Patent Document

[Non-Patent Document 1] T. Mizutani, M. Ito, S. Kishimoto and F. Nakamura, IEEE Electron Device Letters, vol. 28, no. 7, pp. 549-551 (2007)

### SUMMARY

According to one aspect of the present disclosure, a semiconductor device includes an electron transit layer; an electron supply layer disposed on or above the electron transit layer; and a capping layer disposed on or above the electron supply layer, wherein a first lattice constant of the electron transit layer is greater than a second lattice constant of the electron supply layer in a direction parallel to a main surface of the electron transit layer.

The object and advantages of the embodiment will be realized and attained by means of the elements and combinations particularly pointed out in the claims. It is to be understood that both the foregoing general description and the following detailed description are exemplary and explanatory and are not restrictive of the invention, as claimed.

### BRIEF DESCRIPTION OF DRAWINGS

FIG. 1 is a cross-sectional view illustrating a semiconductor device according to a first embodiment;

FIGS. 2A to 2C are cross-sectional views each illustrating a stacked structure;

FIGS. 3A and 3B are graphs each illustrating a relationship between a thickness of a capping layer and sheet resistance;

FIG. 4 is a cross-sectional view (Part 1) illustrating a method for fabricating a semiconductor device according to a first embodiment;

FIG. 5 is a cross-sectional view (Part 2) illustrating the method for fabricating the semiconductor device according to the first embodiment;

FIG. 6 is a cross-sectional view (Part 3) illustrating the method for fabricating the semiconductor device according to the first embodiment;

FIG. 7 is a cross-sectional view (Part 4) illustrating the method for fabricating the semiconductor device according to the first embodiment;

FIG. 8 is a cross-sectional view (Part 5) illustrating the method for fabricating the semiconductor device according to the first embodiment;

FIG. 9 is a cross-sectional view (Part 6) illustrating the method for fabricating the semiconductor device according to the first embodiment;

FIG. 10 is a cross-sectional view illustrating a semiconductor device according to a second embodiment;

FIG. 11 is a cross-sectional view (Part 1) illustrating the method for fabricating the semiconductor device according to the second embodiment;

FIG. 12 is a cross-sectional view (Part 2) illustrating the method for fabricating the semiconductor device according to the second embodiment;

FIG. 13 is a cross-sectional view (Part 3) illustrating the method for fabricating the semiconductor device according to the second embodiment;

FIG. 14 is a cross-sectional view (Part 4) illustrating the method for fabricating the semiconductor device according to the second embodiment;

FIG. 15 is a cross-sectional view illustrating a semiconductor device according to a third embodiment;

FIG. 16 is a cross-sectional view (Part 1) illustrating the method for fabricating the semiconductor device according to the third embodiment;

FIG. 17 is a cross-sectional view (Part 2) illustrating the method for fabricating the semiconductor device according to the third embodiment;

FIG. 18 is a cross-sectional view (Part 3) illustrating the method for fabricating the semiconductor device according to the third embodiment;

FIG. 19 is a cross-sectional view (Part 4) illustrating a method for fabricating a semiconductor device according to a third embodiment;

FIG. 20 is a cross-sectional view (Part 5) illustrating the method for fabricating the semiconductor device according to the third embodiment;

FIG. 21 is a cross-sectional view (Part 6) illustrating the method for fabricating the semiconductor device according to the third embodiment;

FIG. 22 is a cross-sectional view illustrating a semiconductor device according to a fourth embodiment;

FIG. 23 is a cross-sectional view (Part 1) illustrating the method for fabricating the semiconductor device according to the fourth embodiment;

FIG. 24 is a cross-sectional view (Part 2) illustrating the method for fabricating the semiconductor device according to the fourth embodiment;

FIG. 25 is a cross-sectional view (Part 3) illustrating the method for fabricating the semiconductor device according to the fourth embodiment;

FIG. 26 is a cross-sectional view (Part 4) illustrating the method for fabricating the semiconductor device according to the fourth embodiment;

FIG. 27 is a cross-sectional view (Part 5) illustrating the method for fabricating the semiconductor device according to the fourth embodiment;

FIG. 28 is a cross-sectional view (Part 6) illustrating the method for fabricating the semiconductor device according to the fourth embodiment;

FIG. 29 is a diagram illustrating a discrete package according to a fifth embodiment;

FIG. 30 is a line diagram illustrating a PFC circuit according to a sixth embodiment;

FIG. 31 is a line diagram illustrating a power supply apparatus according to a seventh embodiment; and

FIG. 32 is a line diagram illustrating an amplifier according to an eighth embodiment.

### DESCRIPTION OF EMBODIMENTS

In the related art configurations of the semiconductor devices, modulation of the concentration of two-dimensional electron gas (2DEG) may appear to affect other properties.

Thus, according to an aspect of the present disclosure, a semiconductor device capable of easily modulating the concentration of a two-dimensional electron gas is provided.

Hereinafter, embodiments of the present disclosure will be described in detail with reference to the accompanying drawings. In the present specification and the drawings, duplicated descriptions of components having substantially the same functional structures may be omitted by providing the same reference numerals.

### First Embodiment

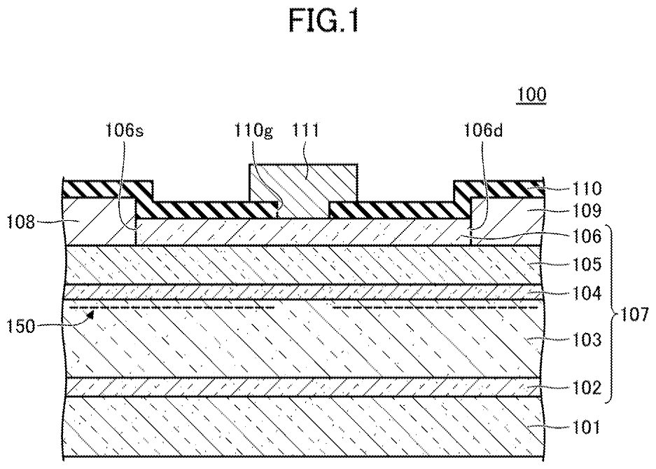

A first embodiment will be described. The first embodiment relates to a semiconductor device having a high-electron-mobility transistor (HEMT) FIG. 1 is a cross-sectional view illustrating a semiconductor device 100 according to the first embodiment.

In the semiconductor device 100 according to the first embodiment, a nitride semiconductor stacked structure 107 is, as illustrated in FIG. 1, formed above the substrate 101. The nitride semiconductor stacked structure 107 includes a nucleation layer 102, a channel layer 103, a spacer layer 104, a barrier layer 105, and a capping layer 106. The nucleation layer 102 is formed on the substrate 101. The channel layer 103 is formed on the nucleation layer 102. The spacer layer 104 is formed on the channel layer 103. The barrier layer 105 is formed on the spacer layer 104. The capping layer 106 is formed on the barrier layer 105. The channel layer 103 is an example of an electronic transit layer, and the barrier layer 105 is an example of an electron supply layer.

The substrate 101 is, for example, a semi-insulating SiC substrate. The nucleation layer 102 is, for example, an AlN layer with a thickness of 5 nm to 150 nm. The channel layer 103 is, for example, a GaN layer with a thickness of 1 μm to 5 μm. The spacer layer 104 is, for example, an Alₓ₁Ga₁₋ₓ₁N layer (0.40≤x1≤1.00) with a thickness of 0.5 nm to 3 nm. That is, the spacer layer 104 is an AlGaN layer having a thickness of, for example, 0.5 nm to 3 nm and an Al composition x1 of greater than or equal to 0.40 and less than or equal to 1.00. The barrier layer 105 is, for example, an Alₓ₂Ga₁₋ₓ₂N layer (0.30≤x2≤0.70) with a thickness of 4 nm to 8 nm. That is, the barrier layer 105 is an AlGaN layer having a thickness of, for example, 4 nm to 8 nm and an Al composition x2 of greater than or equal to 0.30 and less than or equal to 0.70. The capping layer 106 is, for example, a GaN layer with a thickness of 8 nm to 12 nm.

The channel layer 103, the spacer layer 104, the barrier layer 105, and the capping layer 106 each have an a-axis in a direction parallel to a main surface of the channel layer 103, and also have a c axis in a direction perpendicular to the main surface of the channel layer 103. In the absence of external forces and strain, a lattice constant a_{GaN} in an a-axis direction of GaN is 3.189 Å, the lattice constant a_{AlN} in the a-axis direction of AlN is 3.112 Å, and a lattice constant a_{AlGaN} in the Al_{y}Ga_{1-y}N with the Al composition y is expressed by the following equation (1).

a_{AlGaN}=a_{GaN}−(a_{GaN}−a_{AlN})×y (1)

In the a-axis direction, a lattice constant a₁₀₃ of the channel layer 103 is the lattice constant a_{GaN}.

The spacer layer 104 is lattice-matched to the channel layer 103. The spacer layer 104 is strained in a tensile direction due to the effect of the channel layer 103. In the a-axis direction, a lattice constant a₁₀₄ of the spacer layer 104 is equivalent to the lattice constant a₁₀₃ of the channel layer 103.

The barrier layer 105 is lattice-matched to neither the spacer layer 104 nor the channel layer 103. The barrier layer 105 is strained in the tensile direction due to the effects of the channel layer 103 and the spacer layer 104, but the tensile strain of the barrier layer 105 is less than the tensile strain of the spacer layer 104. That is, the tensile strain of the barrier layer 105 is partially relaxed. The percentage of the tensile strain relaxation is, for example, approximately 10% to 30%. In the a-axis direction, a lattice constant a₁₀₅ of the barrier layer 105 is less than the lattice constant a₁₀₄ of the spacer layer 104, and is less than the lattice constant a₁₀₃ of the channel layer 103. Also, the lattice constant a₁₀₅ of the barrier layer 105 is greater than the lattice constant a_{AlGaN} obtained by substituting x2 for y in the above equation (1) Accordingly, the lattice constant a₁₀₅ of the barrier layer 105 is greater than the lattice constant a_{AlGaN} and less than the lattice constant a_{GaN}. For example, a main surface of the barrier layer 105 may include crystal defects such as dislocations, with the main surface of the barrier layer 105 being oriented toward the channel layer 103. Note that when percentage of the relaxation is 0%, the lattice constant a₁₀₅ of the barrier layer 105 matches the lattice constant a_{GaN}, and when percentage of the relaxation is 100%, the lattice constant a₁₀₅ of the barrier layer 105 matches the lattice constant a_{AlGaN}.

The capping layer 106 is lattice-matched to the barrier layer 105. The capping layer 106 is strained in a compression direction. In the a-axis direction, the lattice constant a₁₀₆ of the capping layer 106 is equivalent to the lattice constant a₁₀₅ of the barrier layer 105.

Thus, in the a-axis direction (in a direction parallel to the main surface of the channel layer 103), the lattice constant a₁₀₃ of the channel layer 103 is greater than the lattice constant a₁₀₅ of the barrier layer 105.

An element separation region is formed in a nitride semiconductor stacked structure 107. The element separation region defines an element region. Within the element region, an opening 106s for the source and an opening 106d for the drain are defined in the capping layer 106. Then, a source electrode 108 is formed in the opening 106s, and a drain electrode 109 is formed in the opening 106d. An insulating film 110 that covers the source and drain electrodes 108 and 109 is formed over the capping layer 106. An opening 110g is defined in the insulating film 110 between the source electrode 108 and the drain electrode 109 in a plan view, and a gate electrode 111 is formed on the insulating film 110 through the opening 110g so as to be in contact with the capping layer 106.

The source and drain electrodes 108 and 109 each include, for example, a 10 nm to 50 nm thick Ta film and a 100 nm to 500 nm thick Al film on the Ta film. The source and drain electrodes 108 and 109 are each in ohmic contact with the nitride semiconductor stacked structure 107. The gate electrode 111 includes, for example, a 10 nm to 50 nm thick Ni film and a 300 nm to 500 nm thick Au film on the Ni film. The gate electrode 111 is in Schottky contact with the nitride semiconductor stacked structure 107. The insulating film 110 includes, for example, a nitride layer having Si, Al, Hf, Zr, Ti, Ta or W, and the insulating film 110 preferably includes a Si nitride (SiN) layer. The thickness of the insulating film 110 may be, for example, 2 nm to 500 nm, and is preferably approximately 100 nm.

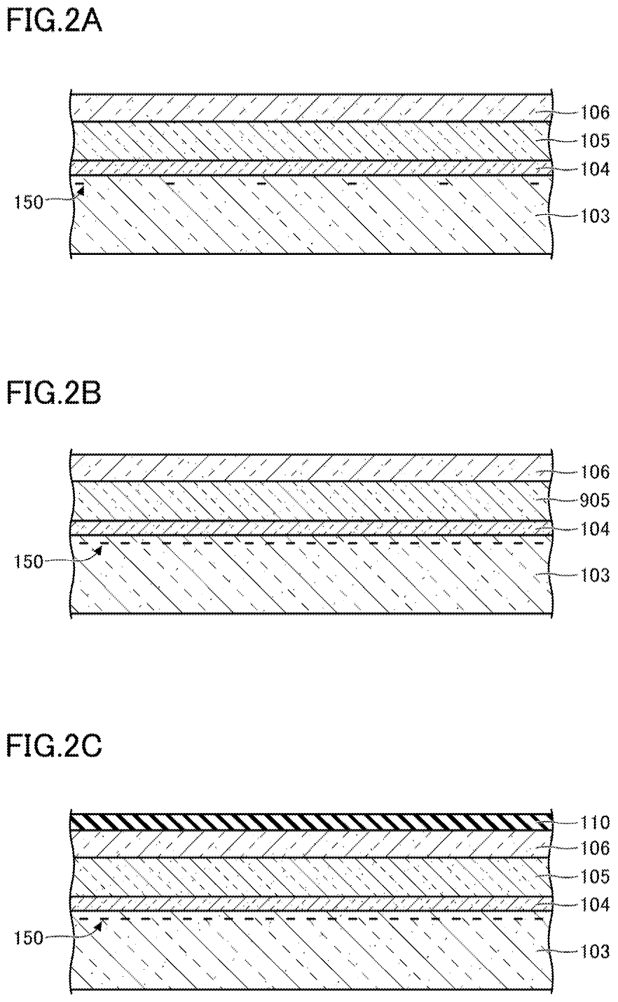

Next, working effects of the barrier layer 105, the capping layer 106, and the insulating film 110 will be described with reference to three types of stacked structures illustrated in FIGS. 2A to 2C. FIGS. 2A to 2C are cross-sectional views each illustrating a stacked structure.

A first stacked structure illustrated in FIG. 2A includes a channel layer 103, a spacer layer 104, a barrier layer 105, and a capping layer 106 in a manner similar to the first embodiment. A second stacked structure illustrated in FIG. 2B includes a barrier layer 905 instead of the barrier layer 105, where the barrier layer 905 is lattice-matched to the channel layer 103 and to the spacer layer 104, and the capping layer 106 is lattice-matched to the channel layer 103, to the spacer layer 104, and to the barrier layer 905. A third stacked structure illustrated in FIG. 2C includes a channel layer 103, a spacer layer 104, a barrier layer 105, a capping layer 106, and an insulating film 110 in a manner similar to the first embodiment.

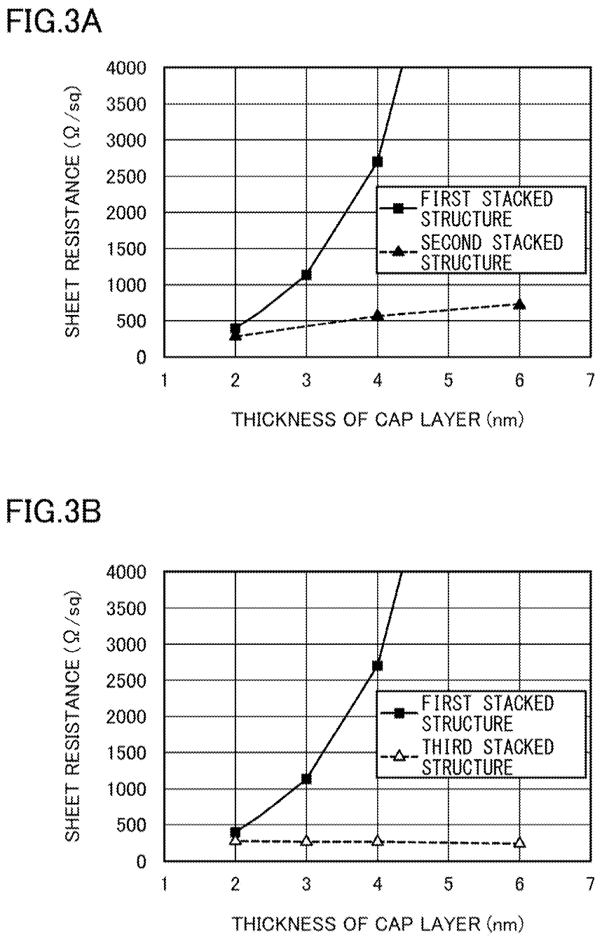

FIGS. 3A and 3B are graphs each illustrating a relationship between the thickness of the capping layer 106 and the sheet resistance in the stacked structure illustrated in FIGS. 2A to 2C. FIG. 3A illustrates a relationship between the first stacked structure and the second stacked structure, and FIG. 3B illustrates a relationship between the first stacked structure and the third stacked structure.

In the first stacked structure (FIG. 2A), the barrier layer 105 is not lattice-matched to the spacer layer 104 and to the channel layer 103, and the tensile strain of the barrier layer 105 is partially relaxed. The capping layer 106 is lattice-matched to the barrier layer 105, and the capping layer 106 is strained in a compression direction. Thus, compression strain is generated in the capping layer 106, causing piezoelectric polarization. Thus, as illustrated in FIG. 3A, the thicker the capping layer 106, the lower the concentration of 2DEG 150 at the surface of the channel layer 103, and the higher the sheet resistance. By contrast, in the second stacked structure (FIG. 2B), the barrier layer 905 is lattice-matched to the channel layer 103 and to the spacer layer 104, and the capping layer 106 is lattice-matched to the channel layer 103, to the spacer layer 104, and to the barrier layer 905. Thus, in the second stacked structure, piezoelectric polarization as in the first stacked structure does not occur in the capping layer 106. Accordingly, even with the thickness of the capping layer 106 being increased, the concentration of 2DEG 150 will not become as low as in the first stacked structure, and the sheet resistance will not become as high as in the first stacked structure.

The third stacked structure (FIG. 2C) includes the first stacked structure, and an insulating film 110 on the capping layer 106. Thus, a positive charge is generated at an interface between the capping layer 106 and the insulating film 110, a conduction band downs, and the concentration of 2DEG 150 is higher than that of the first stacked structure and is substantially the same as that of the second stacked structure. Accordingly, the sheet resistance in the third stacked structure is substantially the same as that of the second stacked structure.

Thus, the concentration of the 2DEG 150 may be adjusted only with or without the addition of the insulating film 110 to the first stacked structure, thereby adjusting the sheet resistance.

In the semiconductor device 100 according to the first embodiment, an insulating film 110 is formed on the capping layer 106, an opening 110g is defined in the insulating film 110, and the gate electrode 111 contacts the capping layer 106 through the opening 110g. Thus, 2DEG 150 is present at high concentration near the top face of the channel layer 103, except beneath the opening 110g. The concentration of 2DEG 150 is extremely low beneath the opening 110g. Thus, the concentration of 2DEG 150 may be easily modulated by the semiconductor device 100. In addition, modulation of the concentration of the 2DEG 150 may achieve a normally-off operation while keeping the on-resistance low.

As illustrated in FIGS. 2A to 2C and FIGS. 3A and 3B, the thicker the capping layer 106, the easier to adjust the concentration of the 2DEG 150, by the presence or the absence of the insulating film 110. Thus, the capping layer 106 is preferably thick, and the thickness of the capping layer 106 is preferably 4 nm or greater. Further, the thinner the barrier layer 105, the easier to adjust the concentration of the 2DEG 150, by the presence or the absence of the insulating film 110. Thus, the barrier layer 105 is preferably thin, and the thickness of the barrier layer 105 is preferably 10 nm.

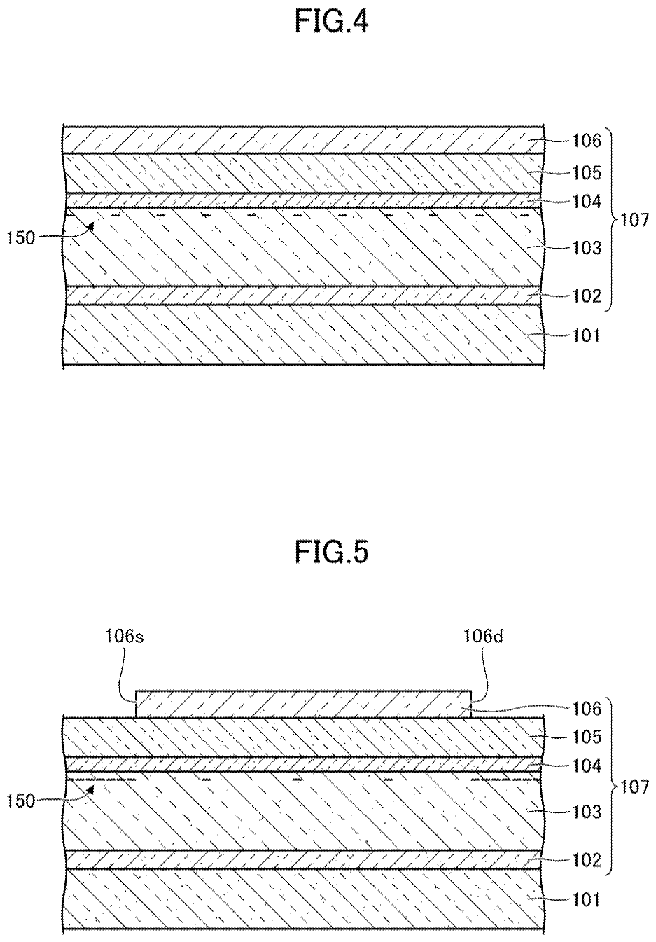

Next, a method for fabricating the semiconductor device 100 according to the first embodiment will be described. FIGS. 4 to 9 are cross-sectional views illustrating a method for fabricating the semiconductor device 100 according to the first embodiment.

First, as illustrated in FIG. 4, a nitride semiconductor stacked structure 107 is formed on the substrate 101. In the formation of the nitride semiconductor stacked structure 107, a nucleation layer 102, a channel layer 103, a spacer layer 104, a barrier layer 105, and a capping layer 106 are formed by, for example, a metal organic vapor phase epitaxy (MOVPE) technique. In the formation of the nitride semiconductor stacked structure 107, a mixture of trimethylgallium (TMGa) gas acting as a Ga source and ammonia (NH₃) gas acting as an N source is used as a precursor for growth of the GaN layer. During the growth of the AlN layer, a mixture of trimethylaluminum (TMal) gas acting as an Al source and NH₃ gas is used as a precursor. During the growth of the AlGaN layer, a mixture of TMAl, TMGa, and NH₃ gases is used as a precursor. Depending on the composition of the nitride semiconductor layer to be grown, the presence or the absence of TMAl and TMGa gas supply and the flow rate are set accordingly. A hydrogen (H₂) gas or nitrogen (N₂) gas is used as a carrier gas. For example, the growth pressure is approximately 1 kPa to 100 kPa and the growth temperature is approximately 700° C. to 1200° C.

Hereinafter, growth conditions of the barrier layer 105 will be described in detail. During the growth of the barrier layer 105, a N₂ gas is used as a carrier gas, and a lower temperature of 700° C. to 800° C. is used as the growth temperature. By adopting such conditions, a barrier layer 105 that is not lattice-matched to the spacer layer 104 and the channel layer 103 may be grown. For example, the percentage of the tensile strain relaxation of the barrier layer 105 may be approximately 10% to 30%. This may be because the use of the low-reducing N₂ gas as a carrier gas causes dislocation under the low temperatures, and the strain is relaxed by dislocation. As in the first stacked structure (see FIG. 2A), the concentration of 2DEG 150 near the top face of the channel layer 103 is extremely low.

After formation of the nitride semiconductor stacked structure 107, an element separation region, defining an element region, is formed in the nitride semiconductor stacked structure 107. In the formation of the element separation region, for example, a photoresist pattern that exposes regions intended to define an element separation region is formed on the nitride semiconductor stacked structure 107, and then ion implantation, such as argon (Ar) ion implantation, is performed using this photoresist pattern as a mask. Dry etching may be performed with a chlorine-based gas using this photoresist pattern as an etching mask.

Thereafter, as illustrated in FIG. 5, an opening 106s and an opening 106d are defined in the capping layer 106. For example, in the defining of openings 106s and 106d, a photoresist pattern that exposes regions intended to define the opening 106s and the opening 106d by photolithography is formed on the nitride semiconductor stacked structure 107, and dry etching is then performed with a chlorine-based gas using this photoresist pattern as an etching mask. A surface protective film may be formed prior to the formation of the photoresist pattern. The surface protective film may, for example, include an oxide layer, a nitride layer, or an oxynitride layer. The oxide layer, the nitride layer, or the oxynitride layer has Si, Al, Hf, Zr, Ti, Ta or W. The surface protective film preferably includes a Si oxide (SiO₂) layer. Beneath the opening 106s and opening 106d, the concentration of 2DEG 150 is high.

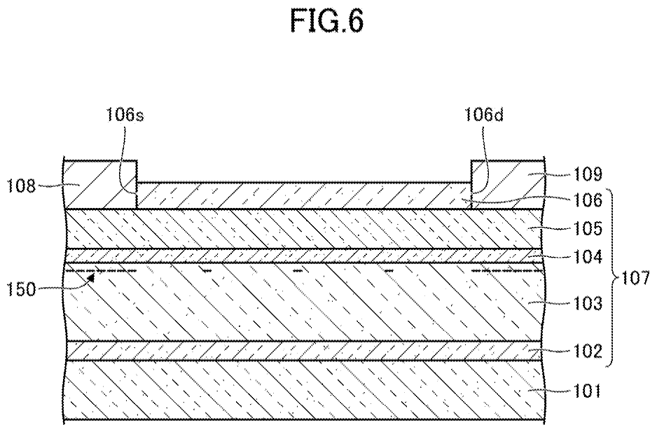

Subsequently, as illustrated in FIG. 6, the source electrode 108 is formed in the opening 106s, and the drain electrode 109 is formed in the opening 106d. The source electrode 108 and the drain electrode 109 may be formed, for example, by the lift-off process. That is, a photoresist pattern that exposes the respective regions intended to form the source electrode 108 and the drain electrode 109 is formed, a metal film is subsequently formed by the deposition process, using the photoresist pattern as a growth mask, and the photoresist pattern is then removed together with the metal film on the photoresist pattern. In the formation of the metal film, for example, a Ta film is formed, and an Al film is formed on the Ta film. Thermal treatment is then performed, for example, at 400° C. to 1000° C. (e.g., 550° C.) in a nitrogen atmosphere to establish ohmic properties.

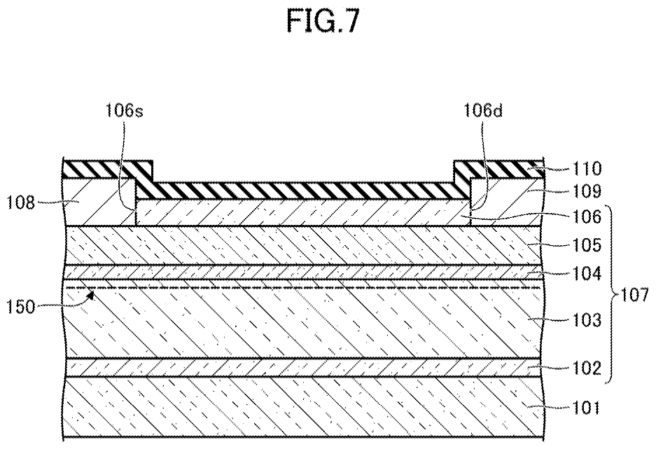

Then, as illustrated in FIG. 7, an insulating film 110 that covers the source and drain electrodes 108 and 109 is formed on the capping layer 106. The insulating film 110 is formed by, for example, the plasma CVD process. The insulating film 110 may be formed by ALD or sputtering. The formation of the insulating film 110 increases the concentration of 2DEG 150 near the top face of the channel layer 103 beneath a region between the source electrode 108 and the drain electrode 109, as in the third stacked structure (see FIG. 2C).

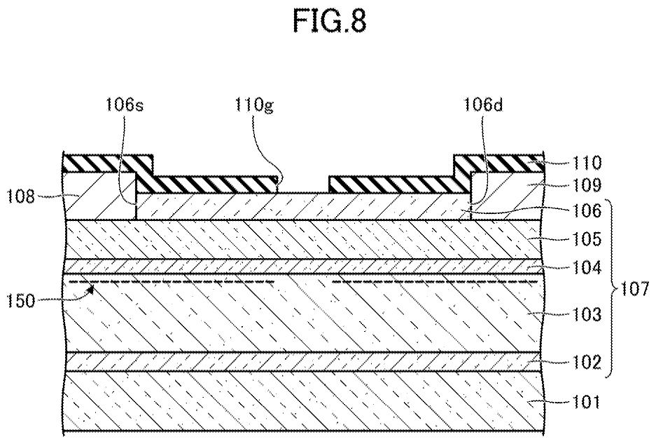

Subsequently, as illustrated in FIG. 8, an opening 110g is defined in the insulating film 110. In defining of the opening 110g, for example, a photoresist pattern that exposes a region intended to define the opening 110g by photolithography is formed on the insulating film 110, and dry etching is performed with a fluorine-based gas or chlorine-based gas using this photoresist pattern as an etching mask. Instead of dry etching, wet etching may be performed using a fluoric acid, buffered fluoric acid, or the like. The formation of opening 110g results in an extremely low the concentration of 2DEG 150 near the top face of channel layer 103 beneath the opening 110g, as in the first stacked structure (see FIG. 2A).

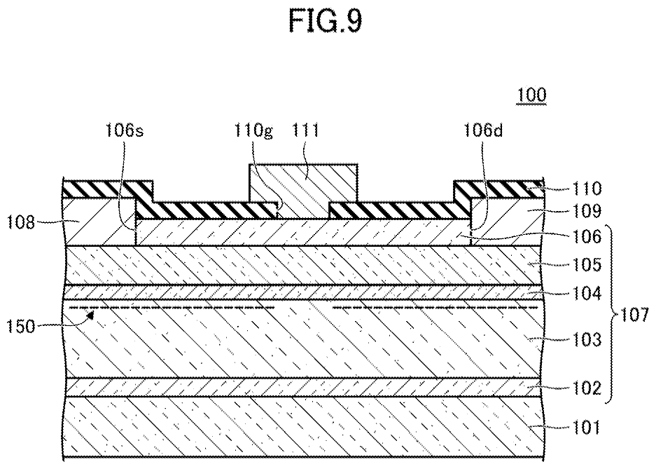

Then, as illustrated in FIG. 9, a gate electrode 111 is formed on the insulating film 110 that contacts the capping layer 106 through the opening 110g. The gate electrode 111 may be formed, for example, by the lift-off process. That is, a photoresist pattern that exposes a region intended to form the gate electrode 111 is formed, a metal film is formed by the deposition process using a photoresist pattern as a growth mask, and the photoresist pattern is removed together with the metal film on the photoresist pattern. In the formation of the metal film, for example, a Ni film is formed, and an Au film is formed on the Ni film.

The semiconductor device 100 according to the first embodiment may be fabricated in this manner.

The barrier layer 105 may be in direct contact with channel layer 103 without the formation of the spacer layer 104. The same applies to the following embodiments.

### Second Embodiment

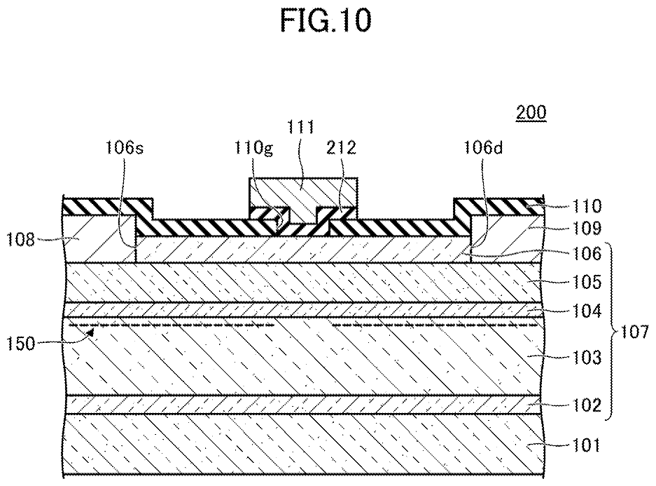

A second embodiment will be described. The second embodiment relates to a semiconductor device having a HEMT. FIG. 10 is a cross-sectional view illustrating a semiconductor device 200 according to the second embodiment.

In the semiconductor device 200 according to a second embodiment, as illustrated in FIG. 10, a gate insulating film 212 is disposed between the gate electrode 111 and the capping layer 106, and also disposed between the gate electrode 111 and the insulating film 110. The gate insulating film 212 includes, for example, an oxide or oxynitride layer. The oxide or oxynitride layer has Si, Al, Hf, Zr, Ti, Ta or W. The gate insulating film 212 may preferably include an Al oxide (Al₂O₃) layer. The thickness of the gate insulating film 212 may, for example, be 5 nm to 20 nm. The gate insulating film 212 is formed locally, e.g., only within a range that overlaps the gate electrode 111 in a plan view.

Other configurations are similar to those of the first embodiment.

The semiconductor device 100 according to the first embodiment employs a Schottky-type gate structure, while the semiconductor device 200 according to the second embodiment employs a MIS (metal-insulator-semiconductor) type gate structure. In the semiconductor device 200, as in the semiconductor device 100, the 2DEG 150 is present at a high concentration near the top face of the channel layer 103 excluding a region beneath the opening 110g, and the concentration of 2DEG 150 is extremely low in the region beneath the opening 110g. Thus, the semiconductor device 200 may readily modulate the concentration of 2DEG 150. In addition, the modulation of the concentration of the 2DEG 150 may achieve a normally-off operation while keeping the on-resistance low.

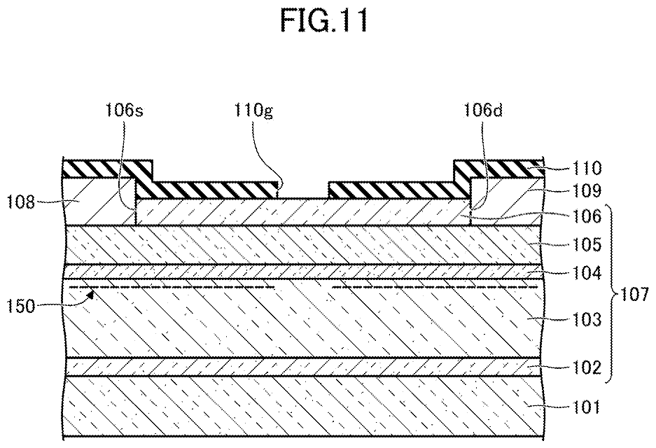

Next, a method for fabricating the semiconductor device 200 according to the second embodiment will be described. FIGS. 11 to 14 are cross-sectional views illustrating a method for fabricating the semiconductor device 200 according to the second embodiment.

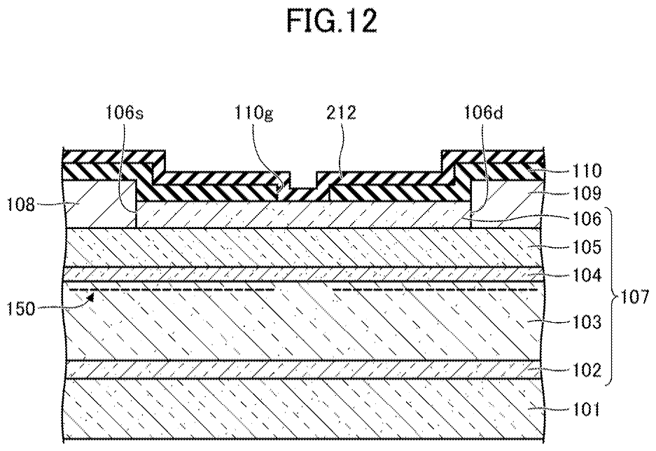

First, as illustrated in FIG. 11, the process up to the defining of the opening 110g is performed in the same manner as in the first embodiment. Then, as illustrated in FIG. 12, the gate insulating film 212 is formed on the insulating film 110. The gate insulating film 212 is formed inside an opening 110g to cover the surface of the capping layer 106. The gate insulating film 212 is formed by, for example, the plasma CVD process. The gate insulating film 212 may be formed by ALD or sputtering.

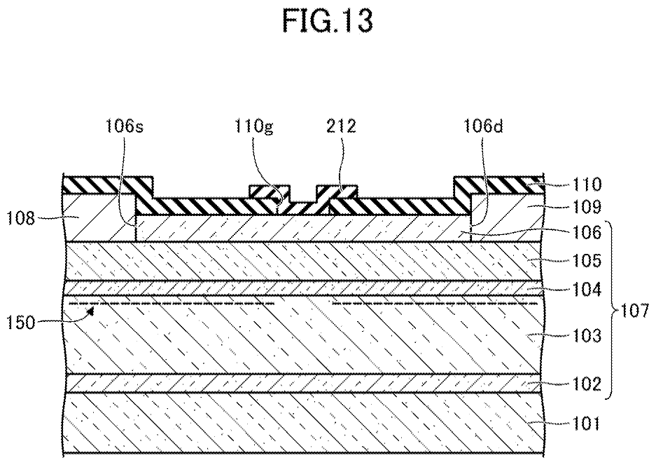

Thereafter, as illustrated in FIG. 13, the gate insulating film 212 is processed to leave the gate insulating film 212 in a region intended to form the gate electrode 111. In the processing of the gate insulating film 212, a photoresist pattern that exposes a region to be removed from the gate insulating film 212 by photolithography is formed on the gate insulating film 212, and dry etching is performed with a fluorine-based or chlorine-based gas using this photoresist pattern as an etching mask. Instead of dry etching, wet etching using a fluoric acid, buffered fluoric acid, or the like may be performed.

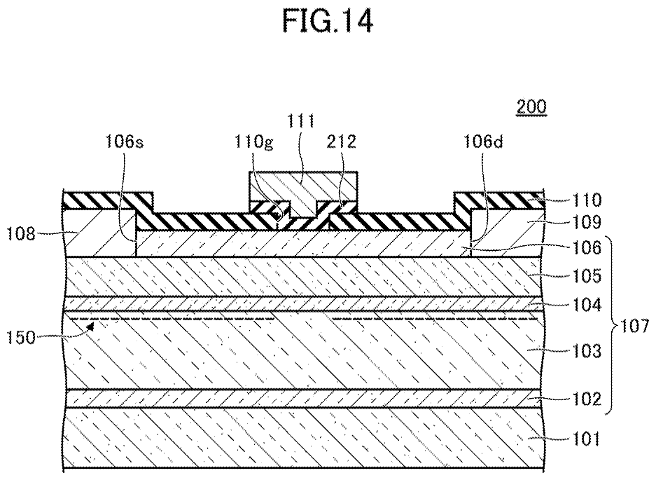

The gate electrode 111 is then formed on the gate insulating film 212 as illustrated in FIG. 14. The gate electrode 111 may be formed by, for example, the lift-off process, as in the first embodiment.

The semiconductor device 200 according to the second embodiment is fabricated in this manner.

### Third Embodiment

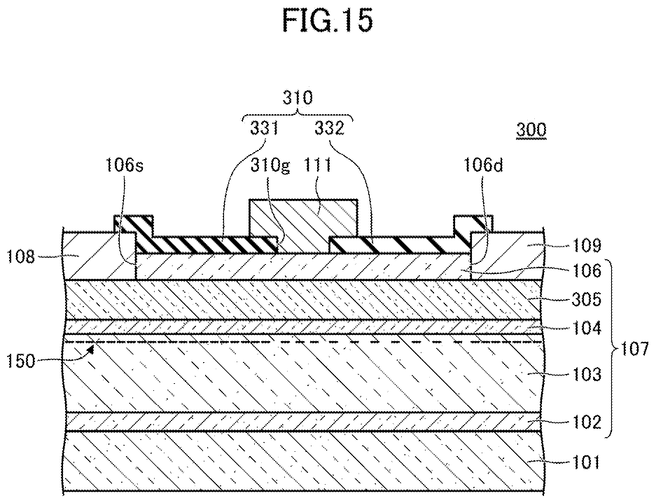

A third embodiment will be described. The third embodiment relates to a semiconductor device having a HEMT. FIG. 15 is a cross-sectional view illustrating a semiconductor device 300 according to the third embodiment.

In the semiconductor device 300 according to the third embodiment, a barrier layer 305 is disposed instead of the barrier layer 105 according to the first embodiment, as illustrated in FIG. 15. Like the barrier layer 105, the barrier layer 305 is not lattice-matched to the spacer layer 104 and the channel layer 103. The barrier layer 305 is strained in the tensile direction due to the effects of the channel layer 103 and the spacer layer 104. However, the tensile strain of the barrier layer 305 is less than the tensile strain of the spacer layer 104. That is, like the barrier layer 105, the tensile strain of the barrier layer 305 is partially relaxed. However, percentage of the relaxation of the tensile strain of the barrier layer 305 is lower than percentage of the relaxation of the tensile strain of the barrier layer 105.

In addition, an insulating film 310 is disposed instead of the insulating film 110 according to the first embodiment. The insulating film 310 includes an insulating film 331 and an insulating film 332. The insulating film 331 covers a portion of the source electrode 108 and extends toward the drain electrode 109. A drain electrode 109 side-end of the insulating film 331 is spaced apart from the drain electrode 109. The insulating film 332 covers a portion of the drain electrode 109, and extends toward the source electrode 108. A source electrode 108 side-end of the insulating film 332 is spaced apart from the source electrode 108. The drain electrode 109 side-end of the insulating film 331 and the source electrode 108 side-end of the insulating film 332 are separated from each other, and an opening 310g of the insulating film 310 is defined between the drain electrode 109 side-end of the insulating film 331 and the source electrode 108 side-end of the insulating film 332. The gate electrode 111 is disposed on the insulating film 310 between the source electrode 108 and the drain electrode 109, and contacts the capping layer 106 through the opening 310g.

The insulating film 331 is a film that is more likely to generate a positive charge than the insulating film 332, at an interface with the capping layer 106. The insulating film 331 includes, for example, a nitride layer having Si, Al, Hf, Zr, Ti, Ta or W, and the insulating film 331 is preferably a Si nitride (SiN) layer. The thickness of the insulating film 331 may be, for example, 2 nm to 500 nm, and is preferably approximately 100 nm. The insulating film 332 includes, for example, an oxide layer or oxynitride layer. The oxide layer or oxynitride layer has Si, Al, Hf, Zr, Ti, Ta or W. The insulating film 332 is preferably an Al oxide (Al₂O₃) layer. The thickness of the insulating film 332 is, for example, 5 nm to 20 nm.

Other configurations are similar to those of the first embodiment.

In the semiconductor device 300 according to the third embodiment, the insulating films 331 and 332 are selectively formed on the capping layer 106, and the insulating film 331 is a film that is more likely to generate a positive charge than the insulating film 332, at the interface with the capping layer 106. Thus, the concentration of 2DEG 150 near the top face of the channel layer 103 is higher beneath the insulating film 331 than beneath the insulating film 332. Thus, the concentration of 2DEG 150 may be easily modulated by the semiconductor device 300. Further, modulation of the concentration of 2DEG 150 may improve drain breakdown voltage while keeping on-resistance low.

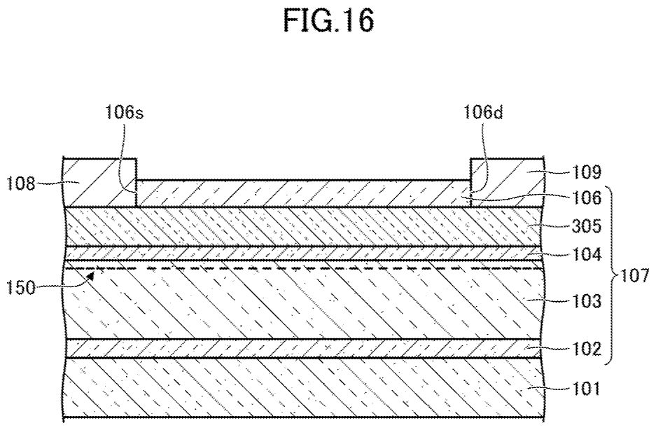

Next, a method for fabricating the semiconductor device 300 according to the third embodiment will be described. FIGS. 16 to 21 are cross-sectional views illustrating a method for fabricating the semiconductor device 300 according to the third embodiment.

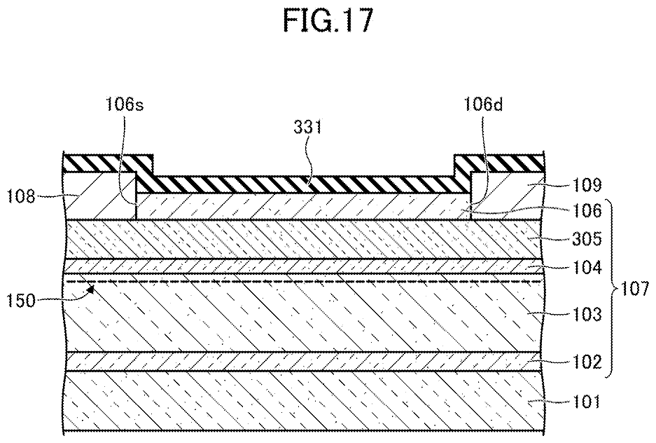

First, as illustrated in FIG. 16, the process up to the formation of the source electrode 108 and the drain electrode 109 is performed, as in the first embodiment. However, a barrier layer 305 is formed instead of the barrier layer 105. Then, as illustrated in FIG. 17, an insulating film 331 is formed on the capping layer 106 so as to cover the source and drain electrodes 108 and 109. The insulating film 331 is formed by, for example, the plasma CVD process. The insulating film 331 may be formed by ALD or sputtering. The formation of the insulating film 331 increases the concentration of 2DEG 150 near the top face of the channel layer 103 beneath a region between the source electrode 108 and the drain electrode 109.

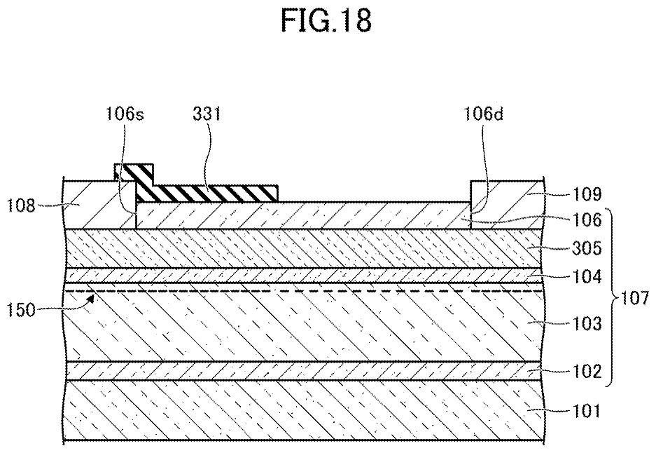

Thereafter, as illustrated in FIG. 18, the insulating film 331 is processed to leave the insulating film 331 between a region intended to define the opening 310g and the source electrode 108. For example, in the processing of the insulating film 331, a photoresist pattern that exposes a region intended to be removed from the insulating film 331 by photolithography is formed on the insulating film 331, and dry etching is performed with a fluorine-based gas or chlorine-based gas using this photoresist pattern as an etching mask. Instead of dry etching, wet etching using a fluoric acid, buffered fluoric acid, or the like may be performed. The processing of the insulating film 331 reduces the concentration of 2DEG 150 near the top face of the channel layer 103 beneath the region intended to define the opening 310g, and beneath a region between the region intended to define the opening 310g and the drain electrode 109.

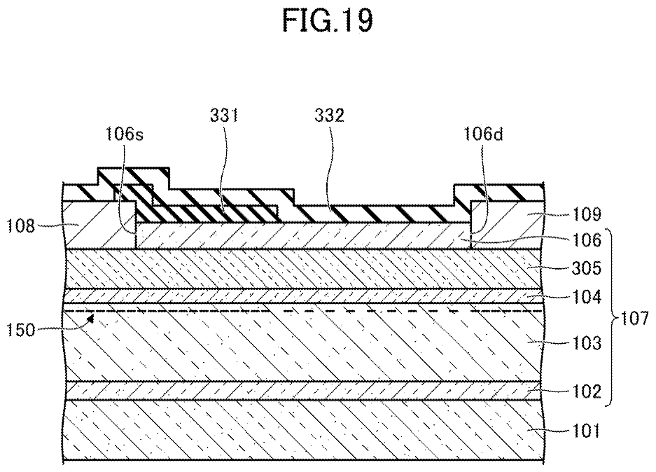

Then, as illustrated in FIG. 19, an insulating film 332 is formed on the capping layer 106 so as to cover the insulating film 331, the source electrode 108, and the drain electrode 109. The insulating film 332 is formed by, for example, the plasma CVD process. The insulating film 332 may be formed by ALD or sputtering. The formation of the insulating film 332 further reduces the concentration of 2DEG 150 near the top face of the channel layer 103 beneath the region where the opening 310g is to be defined and beneath the area between the area where the opening 310g is to be defined and the drain electrode 109.

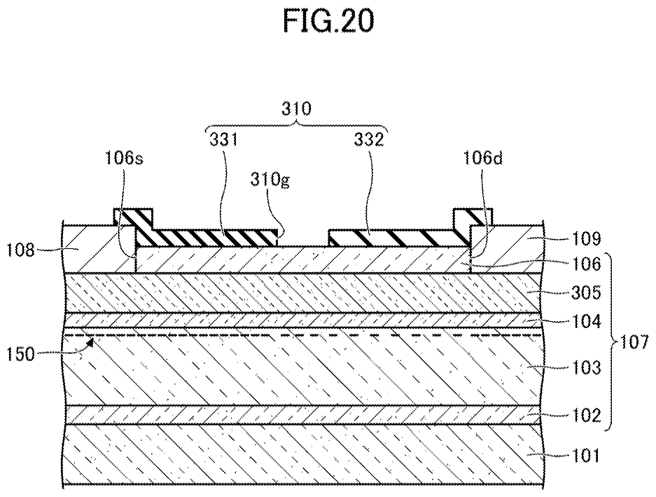

The insulating film 332 is then processed to leave the insulating film 332 between a region intended to define the opening 310g and the drain electrode 109, as illustrated in FIG. 20. In the process of the insulating film 332, a photoresist pattern that exposes a region intended to be removed from the insulating film 332 by photolithography is formed on the insulating film 332, and dry etching is performed with a fluorine-based gas or chlorine-based gas using this photoresist pattern as an etching mask. Instead of dry etching, wet etching using a fluoric acid, buffered fluoric acid, or the like may be performed.

In this manner, the insulating film 310 includes the insulating films 331 and 332, and the insulating film 310 has an opening 310g between the insulating film 331 and the insulating film 332. The processing of the insulating film 332 increases the concentration of 2DEG 150 near the top face of the channel layer 103 beneath the opening 110g.

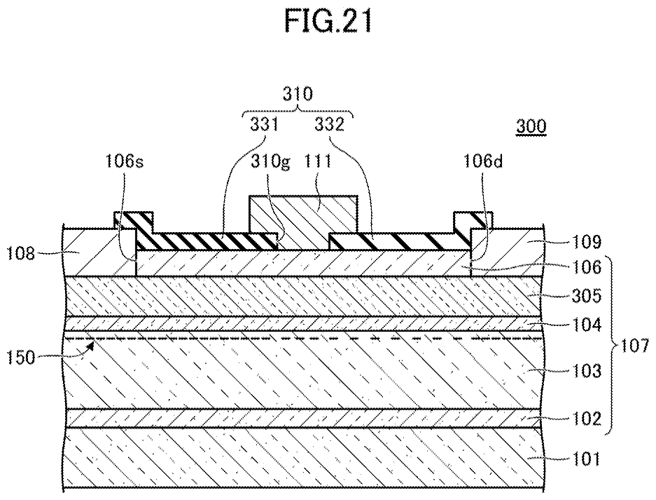

Then, as illustrated in FIG. 21, a gate electrode 111 is formed on the insulating film 310 that contacts the capping layer 106 through the opening 310g. The gate electrode 111 may be formed by, for example, the lift-off process, as in the first embodiment.

The semiconductor device 300 according to the third embodiment is fabricated in this manner.

### Fourth Embodiment

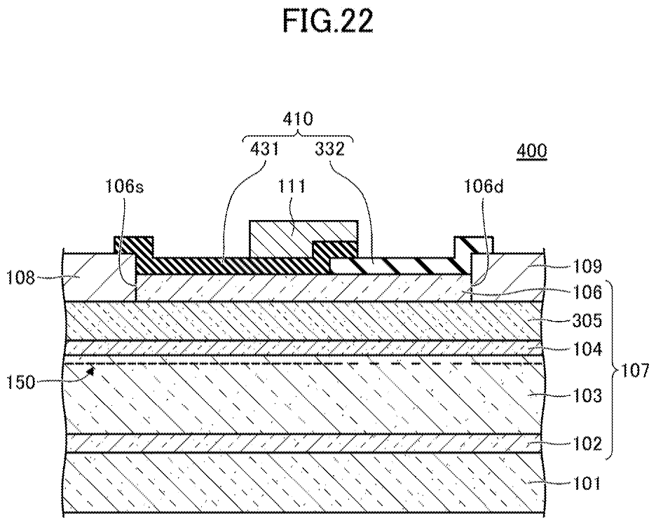

A fourth embodiment will be described. The fourth embodiment relates to a semiconductor device having a HEMT. FIG. 22 is a cross-sectional view illustrating a semiconductor device 400 according to the fourth embodiment.

In the semiconductor device 400 according to the fourth embodiment, as illustrated in FIG. 22, an insulating film 410 is provided instead of the insulating film 310 according to the third embodiment. The insulating film 410 includes an insulating film 431 and an insulating film 332. The insulating film 431 covers a portion of the source electrode 108 and extends toward the drain electrode 109. A drain electrode 109 side-end of the insulating film 431 is spaced apart from the drain electrode 109. The insulating film 332 covers a portion of the drain electrode 109 and extends toward the source electrode 108. A source electrode 108 side-end of the insulating film 332 is spaced apart from the source electrode 108. The drain electrode 109 side-end of the insulating film 431 overlaps the source electrode 108 side-end of the insulating film 332. A gate electrode 111 is disposed on the insulating film 410 between the source electrode 108 and the drain electrode 109. The source electrode 108 side-end of the insulating film 332 is beneath the gate electrode 111. That is, in a plan view, the gate electrode 111 overlaps with a portion of the insulating film 332.

The insulating film 431 is a film that is more likely to generate a positive charge than the insulating film 332, at the interface with the capping layer 106. The insulating film 431 includes, for example, a nitride layer of Si, Al, Hf, Zr, Ti, Ta, or W, and is preferably a Si nitride (SiN) layer. The thickness of the insulating film 431 may be, for example, 2 nm to 500 nm, and is preferably approximately 100 nm.

Other configurations are the same as in the third embodiment.

In the semiconductor device 300 according to the third embodiment, a Schottky-type gate structure is employed, while in the semiconductor device 400 according to the fourth embodiment, a MIS-type gate structure is employed. Also, in the semiconductor device 400, the insulating films 431 and 332 are selectively formed on the capping layer 106, and the insulating film 431 is a film that is more likely to generate a positive charge than the insulating film 332, at the interface with the capping layer 106. Thus, the concentration of 2DEG 150 near the top face of the channel layer 103 is higher beneath the insulating film 431 than beneath the insulating film 332. Thus, the semiconductor device 400 may easily modulate the concentration of 2DEG 150. Further, modulation of the concentration of 2DEG 150 may improve drain breakdown voltage while keeping on-resistance low. Further, the insulating film 332 is disposed on the capping layer 106 beneath the gate electrode 111 in a plan view, so that the concentration of 2DEG 150 is kept low beneath the gate electrode 111.

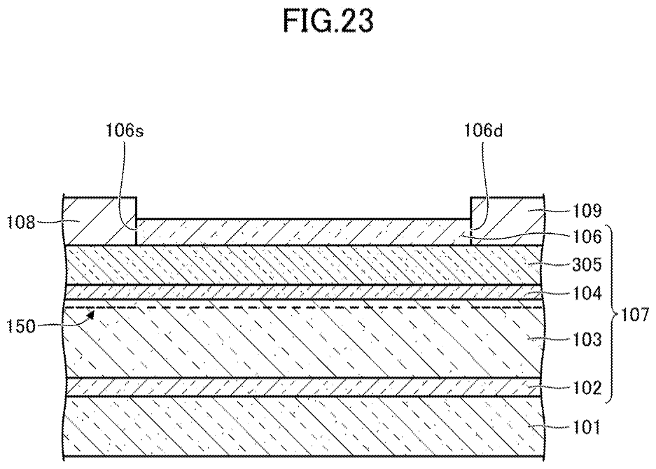

Next, a method for fabricating the semiconductor device 400 according to the fourth embodiment will be described. FIGS. 23 to 28 are cross-sectional views illustrating a method for fabricating the semiconductor device 400 according to the fourth embodiment.

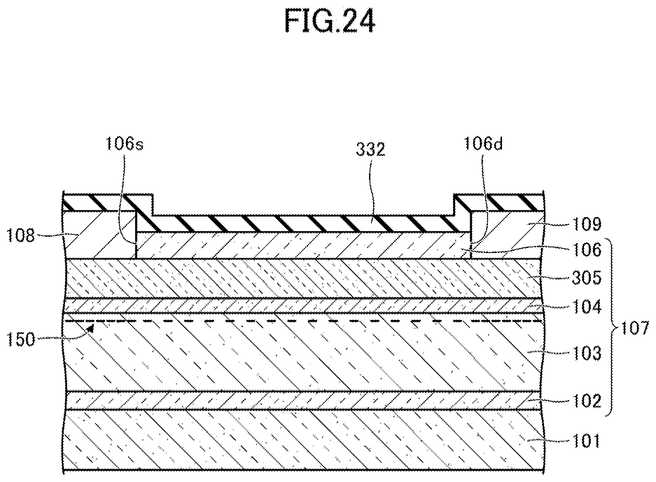

First, as illustrated in FIG. 23, the process up to the formation of the source electrode 108 and the drain electrode 109 is performed in the same manner as in the third embodiment. An insulating film 332 is then formed on the capping layer 106 so as to cover the source electrode 108 and the drain electrode 109, as illustrated in FIG. 24. The insulating film 332 is formed by, for example, the plasma CVD process. The insulating film 332 may be formed by ALD or sputtering. The formation of the insulating film 332 lowers the concentration of 2DEG 150 near the top face of the channel layer 103 beneath a region between the source electrode 108 and the drain electrode 109.

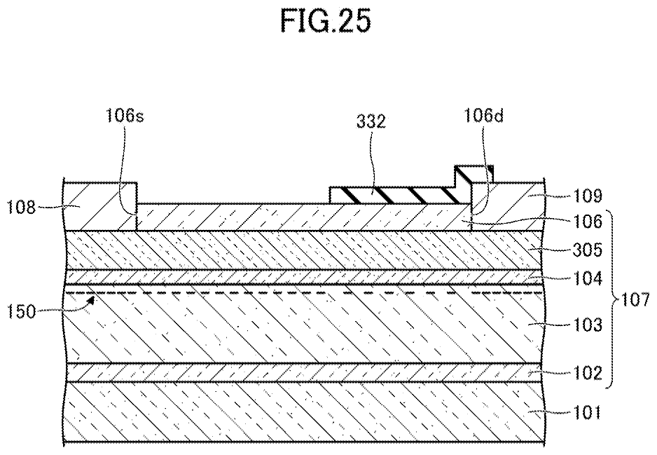

Thereafter, as illustrated in FIG. 25, the insulating film 332 is processed to leave the insulating film 332 so as to cover a portion of the drain electrode 109, and extend toward the source electrode 108. The processing of the insulating film 332 increases the concentration of 2DEG 150 near the top face of the channel layer 103 beneath a region between the source electrode 108 and a source electrode 108 side-end of the insulating film 332.

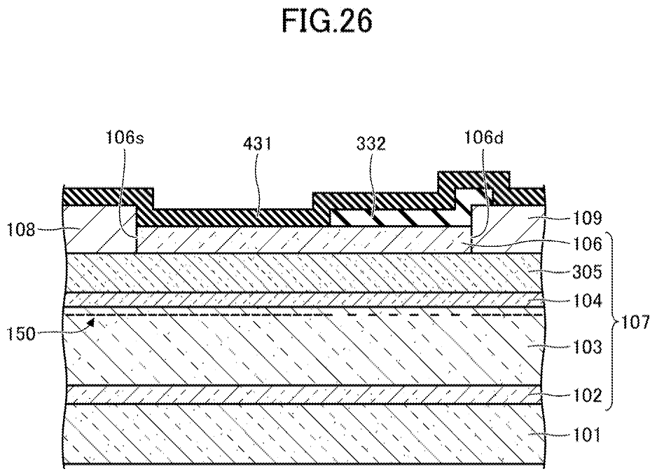

Then, as illustrated in FIG. 26, an insulating film 431 is formed on the capping layer 106 so as to cover the insulating film 332, the source electrode 108, and the drain electrode 109. The insulating film 431 is formed by, for example, the plasma CVD process. The insulating film 431 may be formed by ALD or sputtering. The formation of the insulating film 431 increases the concentration of 2DEG 150 near the top face of the channel layer 103 beneath the region between the source electrode 108 and the source electrode 108 side-end of the insulating film 332.

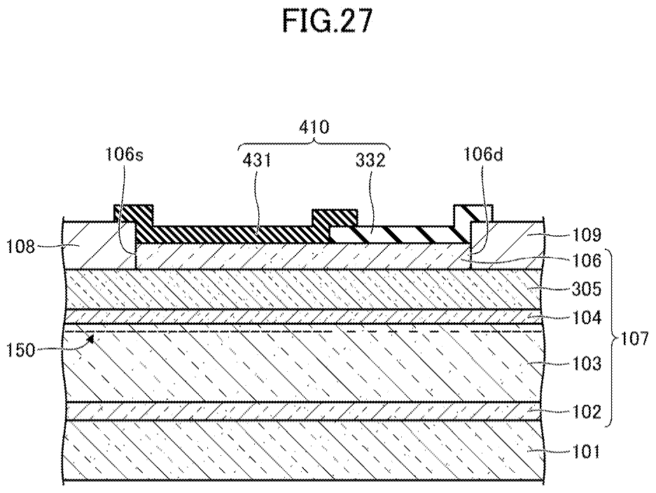

The insulating film 431 is then processed to leave the insulating film 431 so as to cover a portion of the source electrode 108, to extend toward the drain electrode 109, and to overlap an end of the insulating film 332, as illustrated in FIG. 27. For example, in the processing of the insulating film 431, a photoresist pattern that exposes a region intended to be removed from the insulating film 431 by photolithography is formed on the insulating film 431, and dry etching is performed with a fluorine-based gas or chlorine-based gas using this photoresist pattern as an etching mask. Instead of dry etching, wet etching using a fluoric acid, buffered fluoric acid, or the like may be performed.

In this manner, the insulating film 410 including insulating films 431 and 332 is formed.

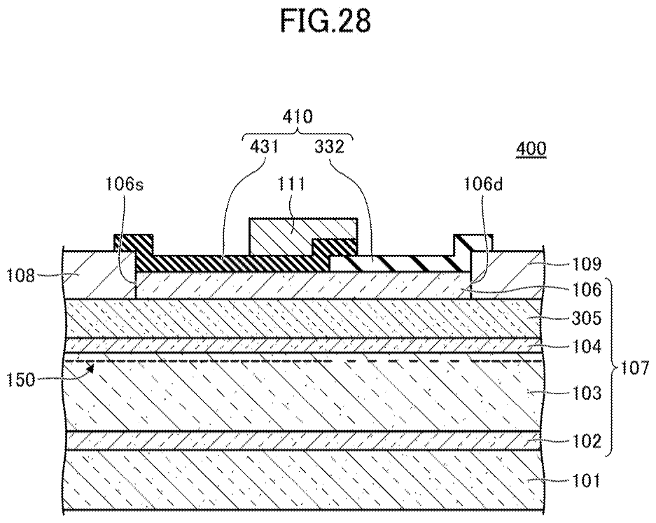

The gate electrode 111 is then formed on the insulating film 431 as illustrated in FIG. 28. The gate electrode 111 may be formed by, for example, the lift-off process, as in the first embodiment.

The semiconductor device 400 according to the fourth embodiment is fabricated in this manner.

### Fifth Embodiment

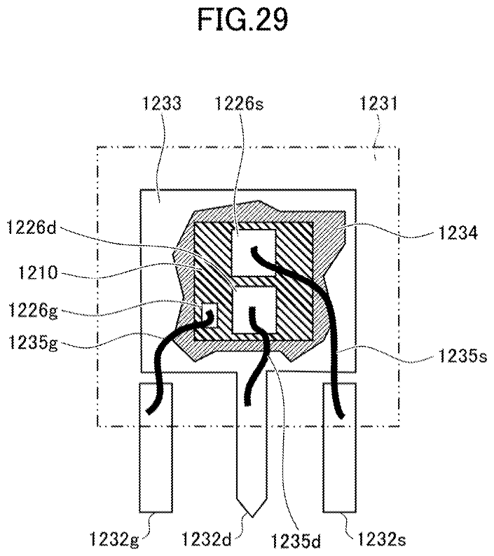

Next, a fifth embodiment will be described. The fifth embodiment relates to a discrete package of a HEMT. FIG. 29 is a diagram illustrating a discrete package according to the fifth embodiment.

In the fifth embodiment, as illustrated in FIG. 29, a back surface of a semiconductor device 1210 having the same structure as any of the first to fourth embodiments is secured to a land (die pad) 1233 with a die attach material 1234, such as solder. One end of a wire 1235d, such as an Al wire, is connected to a drain pad 1226d to which the drain electrode 109 is connected, and the other end of the wire 1235d is connected to a drain lead 1232d integral with the land 1233. One end of a wire 1235s, such as Al wire, is connected to a source pad 1226s to which the source electrode 108 is connected, and the other end of the wire 1235s is connected to a source lead 1232s independent of the land 1233. One end of a wire 1235g, such as Al wire, is connected to a gate pad 1226g to which the gate electrode 111 is connected, and the other end of the wire 1235g is connected to a gate lead 1232g independent of the land 1233. The land 1233 and the semiconductor device 1210 are then packaged with a mold resin 1231 so that a portion of the gate lead 1232g, a portion of the drain lead 1232d, and a portion of the source lead 1232s protrude.

Such a discrete package may be fabricated, for example, as follows. First, the semiconductor device 1210 is secured to the land 1233 of a lead frame using the die attach material 1234, such as solder. The gate pad 1226g is then connected to the gate lead 1232g of the lead frame by bonding using wires 1235g, 1235d and 1235s, the drain pad 1226d is connected to the drain lead 1232d of the lead frame, and the source pad 1226s is connected to the source lead 1232s of the lead frame. Thereafter, the transfer mold process is performed using a mold resin 1231 for sealing. The lead frame is then disconnected.

### Sixth Embodiment

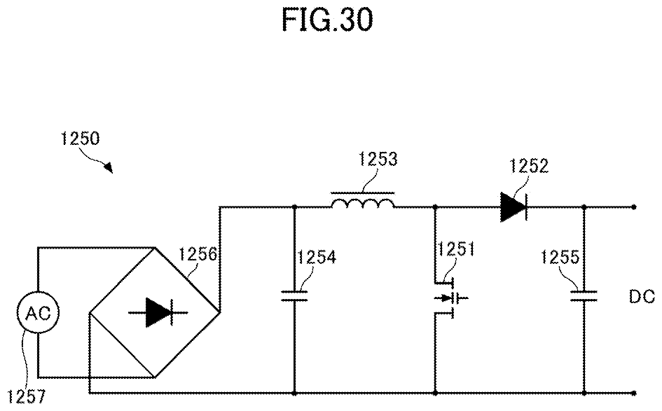

Next, a sixth embodiment will be described. A sixth embodiment relates to a PFC (Power Factor Correction) circuit with a HEMT. FIG. 30 is a line diagram illustrating a PFC circuit 1250 according to the sixth embodiment.

The PFC circuit 1250 is provided with a switch element (transistor) 1251, a diode 1252, a choke coil 1253, capacitors 1254 and 1255, a diode bridge 1256, and an AC power supply (AC) 1257. A drain electrode of the switch element 1251 is connected to an anode terminal of the diode 1252 and one terminal of the choke coil 1253. A source electrode of the switch element 1251 is connected to one terminal of the capacitor 1254 and one terminal of the capacitor 1255. The other terminal of the capacitor 1254 is connected to the other terminal of the choke coil 1253. The other terminal of the capacitor 1255 is connected to a cathode terminal of the diode 1252. A gate driver is also connected to the gate electrode of the switch element 1251. The AC 1257 is connected between the terminals of the capacitor 1254 via the diode bridge 1256. A DC power supply (DC) is connected between the terminals of the capacitor 1255. In this sixth embodiment, the switch element 1251 is provided with a semiconductor device having the same structure as any of the first to fourth embodiments.

In the fabrication of the PFC circuit 1250, for example, solder or the like is used to connect the switch element 1251 to the diode 1252, the choke coil 1253, and the like.

### Seventh Embodiment

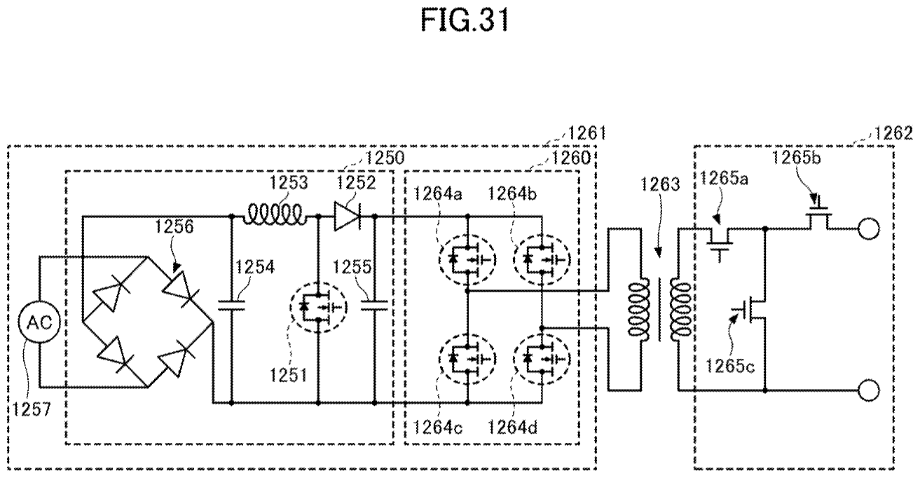

Next, a seventh embodiment will be described. The seventh embodiment relates to a power supply apparatus having a HEMT suitable for server power supply. FIG. 31 is a line diagram illustrating a power supply apparatus according to the seventh embodiment.

The power supply is provided with a high voltage primary circuit 1261, a low voltage secondary circuit 1262, and a transformer 1263 disposed between the primary circuit 1261 and the secondary circuit 1262.

The primary circuit 1261 is provided with a PFC circuit 1250 according to the sixth embodiment and an inverter circuit, such as a full bridge inverter circuit 1260, which is connected between the terminals of the capacitor 1255 of the PFC circuit 1250. The full bridge inverter circuit 1260 is provided with a plurality (four, in this example) of switch elements 1264a, 1264b, 1264c and 1264d.

The secondary circuit 1262 is provided with a plurality (three, in this example) of switch elements 1265a, 1265b and 1265c.

In this seventh embodiment, a semiconductor device having the same structure as in any of the first to fourth embodiments is used for the switch element 1251 of the PFC circuit 1250, and the switch elements 1264a, 1264b, 1264c, and 1264d of the full bridge inverter circuit 1260, which form the primary circuit 1261. Conversely, a related art MIS-type FET (field effect transistor) using silicon is used for the switch elements 1265a, 1265b and 1265c of the secondary circuit 1262.

### Eighth Embodiment

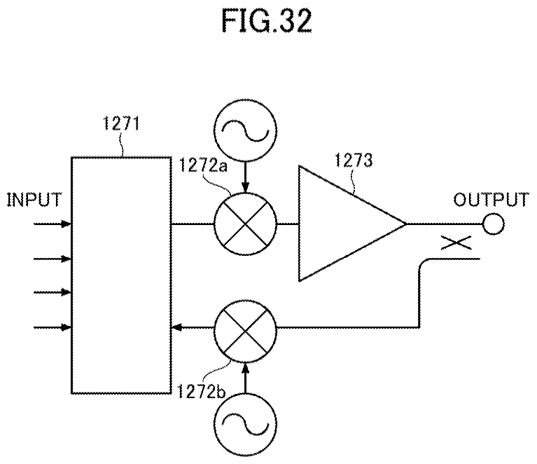

Next, an eighth embodiment will be described. The eighth embodiment relates to an amplifier having a HEMT. FIG. 32 is a line diagram illustrating an amplifier according to the eighth embodiment.

The amplifier is provided with a digital prestrain circuit 1271, mixers 1272a and 1272b, and a power amplifier 1273.

The digital prestrain circuit 1271 compensates for a nonlinear strain of input signals. The mixer 1272a mixes non-linear strain compensated input signals, and AC signals. The power amplifier 1273 includes a semiconductor device having the same structure as any of the first to fourth embodiments to amplify an input signal mixed with an alternating current signal. In this embodiment, for example, by switching the switching elements, an output signal may be mixed with an alternating current signal by the mixer 1272b, and the mixed signals may be transmitted to the digital prestrain circuit 1271. The amplifier may be used as a high-frequency amplifier, or a high-power amplifier. The high-frequency amplifier may be used, for example, in transmitting and receiving devices for mobile phone base stations, radar devices, and microwave generators.

The substrate may be a silicon carbide (SiC) substrate, a sapphire substrate, a silicon substrate, an AlN substrate, a GaN substrate, or a diamond substrate. The substrate may be either electrically conductive, semi-insulating or insulating.

The structures of the gate, source and drain electrodes are not limited to those of the embodiments described above. For example, the structures may be composed of monolayers. In addition, these forming methods are not limited to the lift-off process. Further, if ohmic properties are obtained, the heat treatment after the forming of the source and drain electrodes may be omitted. Heat treatment may be performed after the formation of the gate electrode.

According to the present disclosure, the compositions of semiconductor layers are not limited to those described in the above embodiments. For example, other nitride semiconductors such as InAlN, InGaAlN, and the like may be used. In growing semiconductor layers containing In, a mixture of trimethylindium (TMIn) gas and a NH₃ gas may be used as a precursor. The precursor may further include a TMAl gas, may further include a TMGa gas, or may further include a TMAl gas and a TMGa gas.

Although the preferred embodiments have been described in detail above, various alterations and substitutions may be made to the above-described embodiments without departing from the scope of the claims.

### Effect of the Invention

In accordance with the present disclosure, a technology for easily modulating concentration of a two-dimensional electron gas is provided.

Preferred embodiments have been described in detail above. However, various alterations and substitutions may be added to the embodiments described above, without limiting by the embodiments described above and without departing from the scope described in the claim.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to illustration of the superiority and inferiority of the invention. Although the embodiment(s) of the present inventions have been described in detail, it should be understood that the various changes, substitutions, and alterations could be made hereto without departing from the spirit and scope of the invention.

What is claimed is:

1. A semiconductor device comprising:
an electron transit layer;
an electron supply layer disposed on or above the electron transit layer; and
a capping layer disposed on or above the electron supply layer,
wherein a first lattice constant of the electron transit layer is greater than a second lattice constant of the electron supply layer in a direction parallel to a main surface of the electron transit layer.

2. The semiconductor device as claimed in claim 1,
wherein the second lattice constant is greater than a third lattice constant, the third lattice constant being derived from a composition of the electron supply layer.

3. The semiconductor device as claimed in claim 1, further comprising:
a spacer layer disposed between the electron transit layer and the electron supply layer, the spacer layer being lattice-matched to the electron transit layer.

4. The semiconductor device as claimed in claim 1, further comprising:
a gate electrode, a source electrode, and a drain electrode, the gate electrode, the source electrode, and the drain electrode being disposed above the electron supply layer; and
a nitride layer selectively formed on the capping layer, the nitride layer being disposed between the source electrode and the drain electrode.

5. The semiconductor device as claimed in claim 4,
wherein the gate electrode is in direct contact with the capping layer.

6. The semiconductor device as claimed in claim 4, comprising:
a gate insulating film disposed between the gate electrode and the capping layer.

7. The semiconductor device as claimed in claim 6,
wherein the gate insulating film includes an oxide layer or an oxynitride layer that has Si, Al, Hf, Zr, Ti, Ta or W.

8. The semiconductor device as claimed in claim 4,
wherein the nitride layer is disposed between the source electrode and the gate electrode.

9. The semiconductor device as claimed in claim 4, comprising:
an oxide layer or an oxynitride layer that has Si, Al, Hf, Zr, Ti, Ta, or W, the oxide layer or the oxynitride layer being disposed between the source electrode and the gate electrode.

10. The semiconductor device as claimed in claim 1,
wherein a main surface of the electron supply layer includes crystal defects, the main surface being oriented toward the electron transit layer.

11. An amplifier comprising the semiconductor device as claimed in claim 1.

12. A power supply apparatus comprising the semiconductor device as claimed in claim 1.
